(19) United States
(12) Patent Application Publication
(10) Pub. No.: US 2008/0170369 A1
(43) Pub. Date: Jul. 17, 2008

(54) HEAT DISSIPATING APPARATUS, HEAT DISSIPATING BASE AND ITS MANUFACTURING METHOD

(76) Inventors: Chin-Ming Chen, Taoyuan Hsien (TW); Yu-Hung Huang, Taoyuan Hsien (TW); Kun-Yu Kuo, Taoyuan Hsien (TW); Sung-Ching Ho, Taoyuan Hsien (TW)

Correspondence Address: BIRCH STEWART KOLASCH & BIRCH, PO BOX 747, FALLS CHURCH, VA, 22040-0747, US

(21) Appl. No.: 11/968,566

(22) Filed: Jan. 2, 2008

(30) Foreign Application Priority Data
Jan. 11, 2007 (TW) 096101101

(51) Int. Cl. H05K 7/20

(52) U.S. Cl. 361/704

(57) ABSTRACT

A heat dissipating apparatus includes a heat dissipating base and a heat dissipating element. The heat dissipating base includes a heat conducting plate and a heat dissipating plate having a hole. The heat conducting plate is disposed in the hole by a way of fitting with the hole and the outer edge of the heat conducting plate is tightly contacted with the inner wall of the hole. The heat dissipating element is disposed on and connected to the heat dissipating base.

### CROSS REFERENCE TO RELATED APPLICATIONS

This Non-provisional application claims priority under 35 U.S.C. §119(a) on Patent Application No(s). 096101101 filed in Taiwan, Republic of China on Jan. 11, 2007, the entire contents of which are hereby incorporated by reference.

### BACKGROUND OF THE INVENTION

1. Field of Invention

The invention relates to a heat dissipating apparatus and a heat dissipating base that are simply manufactured and assembled, as well as the manufacturing method thereof.

2. Related Art

Due to the development of technology, varies electronic products, such as the central processing unit (CPU) or chipsets, are developed toward the trend of more powerful functions and smaller sizes. Thus, the high integration of electronic devices in the same chip area needs high heat dissipation. The heat dissipation efficiency directly affects the reliability and lifetime of electronic products.

Take the heat dissipating structure of a central processing unit (CPU) as an example. A heat dissipating apparatus is usually disposed on and in contact with the CPU by gluing, buckling, or soldering for dissipating heat produced by the CPU. In the related art, a fan is often added above the heat dissipating apparatus to enhance the heat dissipating performance. To reduce the cost, the conventional heat dissipating apparatus is usually made of a single material, such as aluminum that has high flexibility and low density. By press or stamp molding, the aluminum can be formed a heat sink with a heat dissipating base and a plurality of heat dissipating fins. However, the heat conductivity of aluminum is low, so the heat cannot be dissipated quickly. If the heat dissipating apparatus is made of copper, which has excellent heat conductivity, is used as the material of the heat sink, however, the cost of producing the heat dissipating apparatus will increase a lot.

To solve the above-mentioned problems, the related art uses a heat dissipating base made of a complex metal structure (e.g., an aluminum-copper compound). This complex metal structure has both the advantages of easy molding and good heat dissipating performance. As shown in FIG. 1, a conventional heat sink 1 includes a heat dissipating base 11 and a plurality of heat dissipating fins 12. For example, the heat sink 1 is disposed on a CPU (not shown). It should be noted that, for the illustration purpose, the heat sink 1 shown in FIG. 1 is disposed upside down. The heat dissipating base 11 consists of an aluminum plate 111 and a copper plate 112. The aluminum plate 111 has a recess 1111, and the copper plate 112 is disposed therein. The copper plate 112 guides the heat produced by the CPU out and transmits it to the aluminum plate 111. The heat is then dissipated by the aluminum plate 111 and the heat dissipating fins 12.

The heat dissipating base 11 is usually fabricated by forging or soldering. The forging technique (cold or hot forging) involves the method of impacting or imposing a pressure on a raw material, thereby changing the shape of the material to meet the internal shape of a mold. However, this method does not only increase the cost of material and equipment for forging, but there are also certain defects in the manufacturing process. In the case of cold forging, material hardening is so strong that the density of metal increases. Once it reaches a certain value density, cracks will appear. This may even damage the forging elements and the molds. In addition, hot forging has to be performed at the temperature of re-crystallization. As metal is easy to be deformed at high temperature, the size of metal after performing hot forging is difficult to control. The molds may be deformed or damaged due to abrasions. The product precision is also affected.

As shown in FIGS. 2A and 2B, if the Al—Cu complex metal of the heat dissipating base 21 is connected by soldering, the copper plate 212 is connected inside an aperture 2111 of the aluminum plate 211. However, this method increases the interface of tin S between the copper plate 212 and the aluminum plate 211. Too many interfaces of different materials reduce the heat conduction. Moreover, the connection between the copper plate 212 and the aluminum plate 211 is likely to have tin overflow. Besides, fluxes are all over working surfaces. This requires the additional cost of re-cleansing. The tightness of tin S between the copper plate 212 and aluminum plate 211 after soldering also directly affects the heat dissipation efficiency. Finally, the assembly of the heat dissipating base 21 and the heat dissipating fins is inconvenient for mold design, and the precision of the component sizes is difficult to control.

Therefore, it is an important subject to provide a heat dissipating apparatus, a heat dissipating base and a manufacturing method thereof that avoid the drawbacks of forging and soldering, involve easy production and assembly to lower costs, and have higher heat conductivity to quickly dissipate heat.

### SUMMARY OF THE INVENTION

In view of the foregoing, the invention is to provide a heat dissipating apparatus, a heat dissipating base and a manufacturing method thereof that avoid the drawbacks of conventional heat dissipating apparatus produced by forging and soldering. In addition, the invention involves simple production and assembly to lower cost, and the heat dissipating apparatus and the heat dissipating base have higher heat conductivity to quickly dissipate heat.

To achieve the above, the invention discloses a heat dissipating apparatus including a heat dissipating base and a heat dissipating element. The heat dissipating base includes a heat conducting plate and a heat dissipating plate having a hole. The heat conducting plate is disposed in the hole by a way of fitting with the hole. The heat dissipating element is disposed on and connected to the heat dissipating base.

To achieve the above, the invention also discloses a heat dissipating base including a heat conducting plate and a heat dissipating plate. The heat dissipating plate has a hole. The heat conducting plate is disposed in the hole by a way of fitting with the hole and an outer edge of the heat conducting plate is tightly contacted with an inner wall of the hole.

To achieve the above, the invention further discloses a manufacturing method of a heat dissipating base. The manufacturing method includes the steps of: providing a heat conducting plate and a heat dissipating plate having a hole and disposing the heat conducting plate in the hole by a way of fitting. The shape of the heat conducting plate corresponds to that of the hole, and the size of the heat conducting plate is slightly larger than that of the hole. Thus, the heat conducting plate is fitted with the hole and an outer edge of the heat conducting plate is tightly contacted with an inner wall of the hole.

As mentioned above, in the heat dissipating apparatus, heat dissipating base and manufacturing method thereof of the invention, the heat dissipating plate is disposed in the hole by a pressing method, so that the outer edge of the heat conducting plate is tightly contacted with the inner wall of the hole. Compared with the related art, the invention avoids the drawbacks of conventional heat dissipating apparatus produced by forging and soldering. The heat dissipating base is tightly contacted with the complex metal to achieve good heat conduction efficiency. The fabrication and assembly are simplified so that the production cost is lowered. Besides, the heat dissipating base is further connected with a heat dissipating element to further enhance the heat conduction efficiency.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic illustration showing a conventional heat dissipating apparatus;

FIG. 2A is a schematic illustration showing a conventional heat dissipating base;

FIG. 2B is a cross-sectional view of the heat dissipating base along a line A-A FIG. 2A;

FIG. 3 is a schematic illustration showing a heat dissipating apparatus according to an embodiment of the invention;

FIGS. 4A and 4B are schematic illustrations of the heat dissipating base according to the embodiment of the invention formed using different ways of fitting, a hot plugging method in FIG. 4A and a cold plugging method in FIG. 4B;

FIG. 5A is a schematic illustration showing a heat dissipating base according to the embodiment of the invention;

FIG. 5B is a cross-sectional view of the heat dissipating base along a line B-B in FIG. 5A;

FIG. 6 is a flowchart of a manufacturing method of a heat dissipating base according to the embodiment of the invention; and

FIG. 7 is a flowchart showing different ways of fitting for disposing the heat conducting plate in the hole.

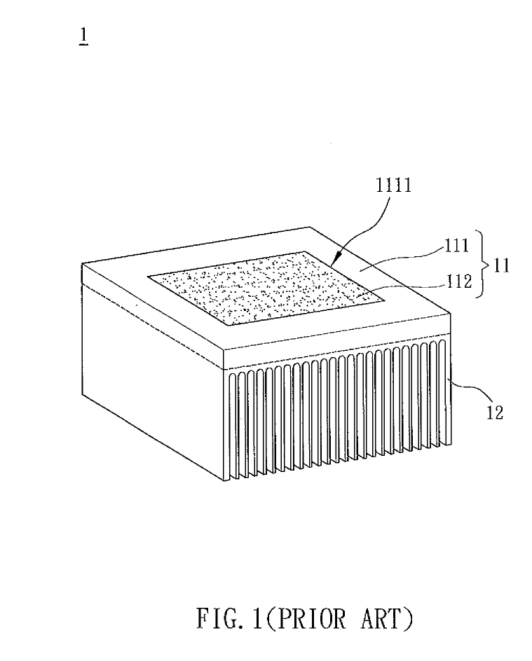

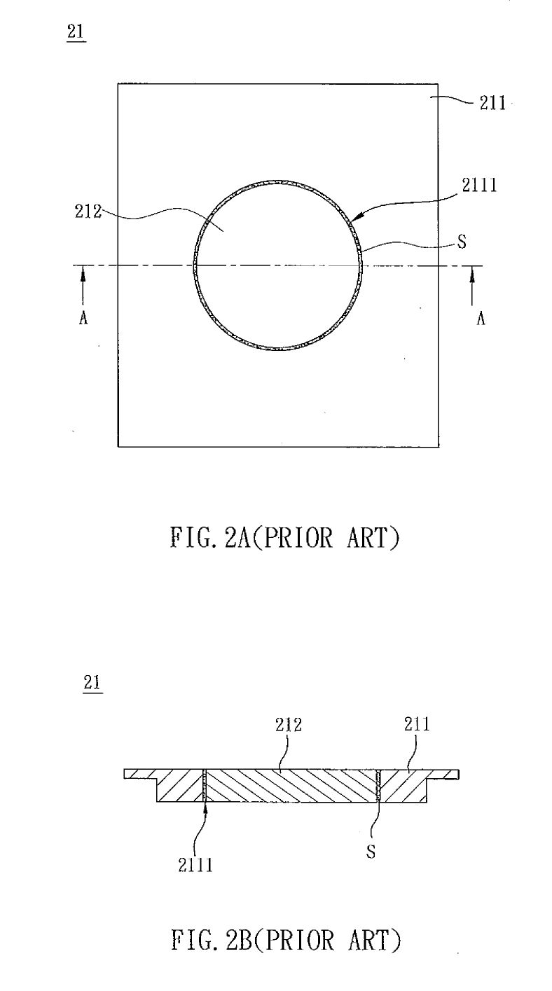

### DETAILED DESCRIPTION OF THE INVENTION

The present invention will be apparent from the following detailed description, which proceeds with reference to the accompanying drawings, wherein the same references relate to the same elements.

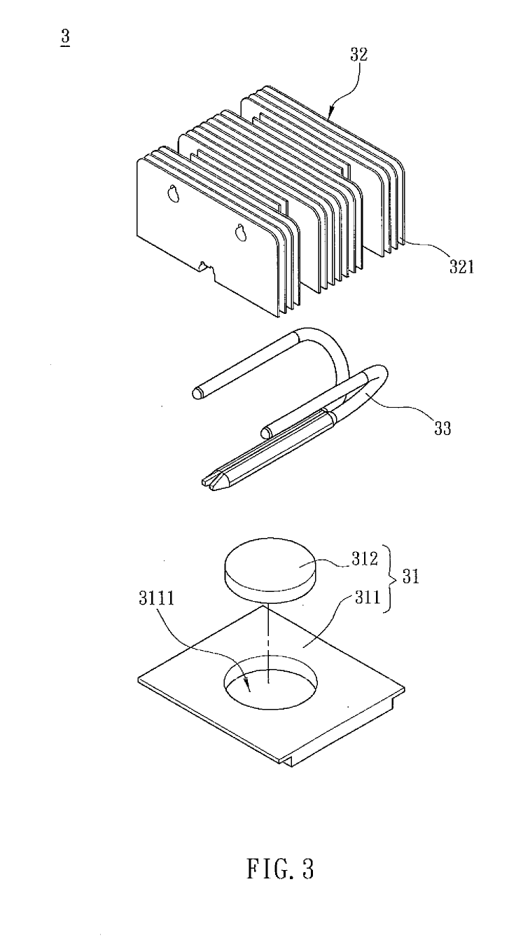

With reference to FIG. 3, a heat dissipating apparatus 3 according to an embodiment of the invention includes a heat dissipating base 31 and a heat dissipating element 32. The heat dissipating base 31 has a heat dissipating plate 311 and a heat conducting plate 312. The heat dissipating plate 311 has a hole 3111, and the shape of the hole 3111 is designed according to the heat conducting plate 312. The heat dissipating plate 311 and the heat conducting plate 312 are made of the same material such as, for example but not limited to, copper, aluminum, alloys thereof or a thermally conducting material.

The shape of the heat conducting plate 312 corresponds to that of the hole 3111. The size of the heat conducting plate 312 is slightly larger than that of the hole 3111. In this embodiment, the shapes of the heat conducting plate 312 and the hole 3111 are both circular.

The heat dissipating element 32 is disposed on and connected with the heat dissipating base 31. They can be connected by gluing, locking, fastening or soldering. The heat dissipating element 32 has several heat dissipating fins 321. In addition, the heat dissipating apparatus 3 further includes at least one heat conducting element 33, which has a first end in touch with the heat dissipating element 32 and a second end in touch with the heat dissipating base 31. In addition to transmitting heat by the direct contact between the heat conducting plate 312 and the heat dissipating element 32, the heat on the heat conducting plate 33 is further transmitted to other positions of the heat dissipating element 32 via the heat conducting element 33. This achieves multi-path heat conduction and dissipation, enhancing the heat conduction efficiency. The heat conducting element 33 in this embodiment can be a heat pipe. The shape of the heat conducting element 33 is, for example but not limited to, a U or C shape. In this case, the heat dissipating apparatus 3 has two U-shaped heat dissipating elements 33 as an example.

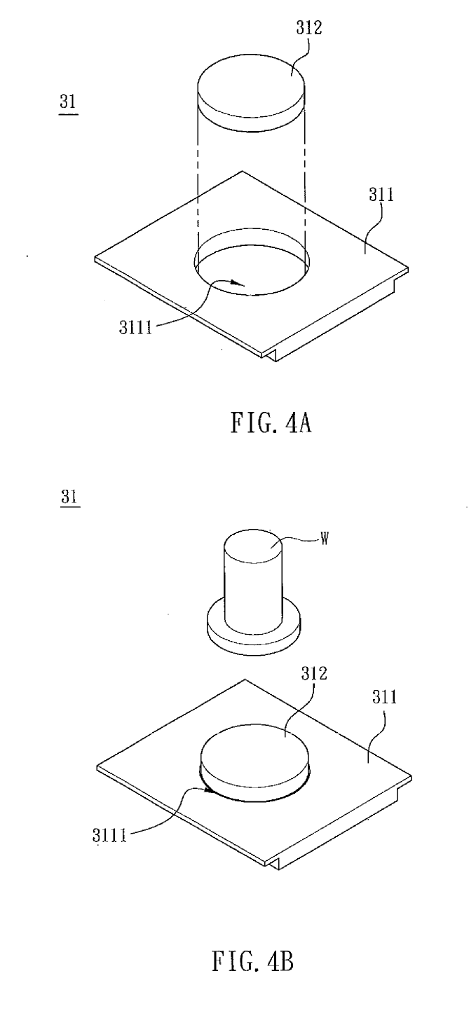

The assembly of the heat conducting plate 312 and the heat dissipating plate 311 is demonstrated in FIGS. 4A and 4B. The heat conducting plate 312 is disposed in the hole 3111 under pressure by a way of fitting, such as a hot plugging method or a cold plugging method. When using the hot plugging method (FIG. 4A), the entire heat dissipating plate 311 or the hole 3111 is heated until the hole 3111 is thermally expanded to a size slightly larger than that of the heat conducting plate 312. Then the heat conducting plate 312 is inserted into the hole 3111 of the heat conducting plate 311. After the heat dissipating plate 311 is cooled down, the outer edge of the heat conducting plate 312 then is tightly contacted with the inner wall of the hole 3111. When using the cold plugging method (FIG. 4B), the heat conducting plate 312 is cooled until the size of the heat conducting plate 312 is slightly smaller than that of the hole 3111. Then the heat conducting plate 312 is inserted into the hole 3111. After the heat conducting plate 312 is warmed up, the outer edge of the heat conducting plate 312 is tightly contacted with the inner wall of the hole 3111. Of course, one can also use a punching head W to impose a pressure on the heat conducting plate 312 directly, embedding it into the hole 3111.

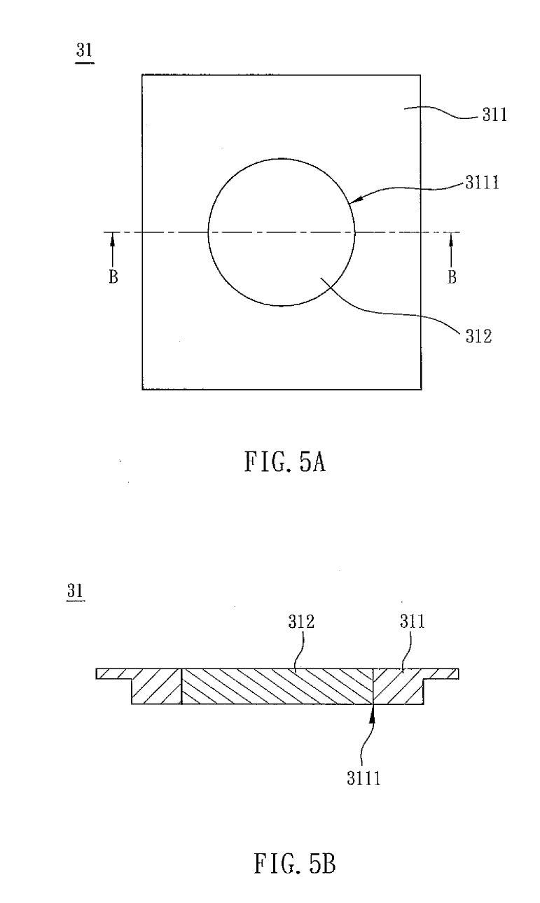

With reference to FIGS. 5A and 5B, the tight contact between the outer edge of the heat conducting plate 312 and the inner wall of the hole 3111 can also be achieved by direct stamping. Heat can be quickly transmitted to the heat dissipating plate 311 via the heat conducting plate 312. Since no soldering is involved between the heat conducting plate 312 and the heat dissipating plate 311, the fabrication and assembly become simpler. The production cost can thus be lowered.

Please refer to FIG. 6 for a manufacturing method of a heat dissipating base according to an embodiment of the invention. The manufacturing method can be applied to the above-mentioned heat dissipating base 31. The method includes steps S10 to 820. In step S10, a heat conducting plate 312 and a heat dissipating plate 311 are provided. The heat dissipating plate 31 has a hole 3111. The shape of the heat conducting plate 312 corresponds to that of the hole 3111, and the size of the heat conducting plate 312 is slightly larger than that of the hole 3111. In step S20, the heat conducting plate 312 is disposed in the hole 3111 under pressure by a way of fitting with the hole 3111 and the outer edge of the heat conducting plate 312 is tightly contacted with the inner wall of the hole 3111.

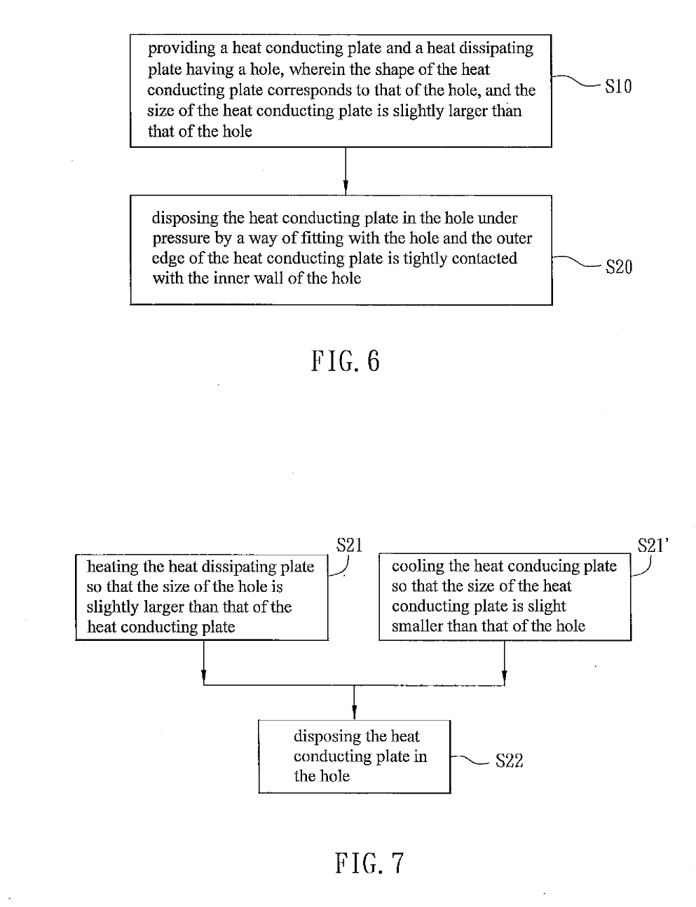

Please refer to FIG. 7. The way of fitting in step S20 can be done by heating (hot plugging), cooling (cold plugging), or direct stamping. In step S21, when the way of fitting is done by heating, the heat dissipating plate 311 is heated so that the size of the hole 3111 is slightly larger than that of the heat conducting plate 312. In step S22, the heat conducting plate 312 is disposed in the hole 3111. After the hole 3111 cools down and contracts, the outer edge of the heat conducting plate 312 is tightly contacted with the inner wall of the hole 3111. In step S21′, when the way of fitting is done by cooling, the heat conducting plate 312 is cooled so that the size of the heat conducting plate 312 is slight smaller than that of the hole 3111. In step S22, the heat conducting plate 312 is disposed in the hole 3111. After the heat conducting plate 312 warms up and expands, the outer edge of the heat conducting plate 312 is tightly contacted with the inner wall of the hole 3111.

In summary, in the heat dissipating apparatus, heat dissipating base and manufacturing method thereof of the invention, the heat dissipating plate is disposed in the hole by a way of fitting, so that the outer edge of the heat conducting plate is tightly contacted with the inner wall of the hole. Compared with the related art, the invention avoids the drawbacks of conventional heat dissipating apparatus produced by forging and soldering. The heat dissipating base is tightly contacted with the complex metal to achieve good heat conduction efficiency. The fabrication and assembly are simplified so that the production cost is lowered. Besides, the heat dissipating base is further connected with a heat dissipating element to further enhance the heat conduction efficiency.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A heat dissipating apparatus comprising:
a heat dissipating base comprising a heat conducting plate and a heat dissipating plate having a hole, wherein the heat conducting plate is disposed in the hole and fits with the hole; and
a heat dissipating element disposed on and connected to the heat dissipating base.

2. The heat dissipating apparatus of claim 1, wherein the heat conducting plate is disposed in the hole under pressure, or by hot plugging, cold plugging, or direct stamping.

3. The heat dissipating apparatus of claim 2, wherein the hot plugging is to heat up the heat dissipating plate so that the hole is slightly larger than the heat conducting plate, dispose the heat conducting plate in the hole of the heat dissipating plate, and cool down the heat dissipating plate to achieve a tight contact between the heat conducting plate and the heat dissipating plate.

4. The heat dissipating apparatus of claim 2, wherein the cold plugging is to cool down the heat conducting plate so that the heat conducting plate is slightly smaller than the hole, dispose the heat conducting plate in the hole of the heat dissipating plate, and warm up the heat conducting plate to achieve a tight contact between the heat conducting plate and the heat dissipating plate.

5. The heat dissipating apparatus of claim 2, wherein a shape of the heat conducting plate corresponds to that of the hole, and a size of the heat conducting plate is slightly larger than that of the hole.

6. The heat dissipating apparatus of claim 1, wherein the heat dissipating plate and the heat conducting plate are made of copper, aluminum, alloys thereof, or a thermally conducting material.

7. The heat dissipating apparatus of claim 1, wherein the heat dissipating element has a plurality of heat dissipating fins connected with the heat dissipating base by gluing, locking, fastening, or soldering.

8. The heat dissipating apparatus of claim 1 further comprising at least one heat conducting element having a first end in contact with the heat dissipating element and a second end in contact with the heat dissipating base.

9. The heat dissipating apparatus of claim 8, wherein the heat conducting element is a heat pipe or has a U shape or a C shape.

10. A heat dissipating base comprising:
a heat conducting plate; and
a heat dissipating plate having a hole, wherein the heat conducting plate is disposed in the hole and fits with the hole, and an outer edge of the heat conducting plate is tightly contacted with an inner wall of the hole.

11. The heat dissipating base of claim 10, wherein the heat conducting plate is disposed in the hole under pressure or by hot plugging, cold plugging, or direct stamping.

12. The heat dissipating base of claim 1, wherein the hot plugging is to heat up the heat dissipating plate so that the hole is slightly larger than the heat conducting plate, dispose the heat conducting plate in the hole of the heat dissipating plate, and cool down the heat dissipating plate to achieve a tight contact between the heat conducting plate and the heat dissipating plate.

13. The heat dissipating base of claim 11, wherein the cold plugging is to cooling down the heat conducting plate so that the heat conducting plate is slightly smaller than the hole, dispose the heat conducting plate in the hole of the heat dissipating plate, and warm up the heat conducting plate to achieve a tight contact between the heat conducting plate and the heat dissipating plate.

14. The heat dissipating base of claim 11, wherein a shape of the heat conducting plate corresponds to that of the hole, and the size of the heat conducting plate is slightly larger than that of the hole.

15. The heat dissipating base of claim 10, wherein the heat dissipating plate and the heat conducting plate are made of copper, aluminum alloys thereof or a thermally conducting material.

16. A method of manufacturing a heat dissipating base, comprising steps of:
providing a heat conducting plate and a heat dissipating plate, wherein the heat dissipating plate has a hole; and
disposing the heat conducting plate in the hole, wherein an outer edge of the heat conducting plate is tightly contacted with an inner wall of the hole.

17. The method of claim 16, wherein a shape of the heat conducting plate corresponds to that of the hole, and a size of the heat conducting plate is slightly larger than that of the hole.

18. The method of claim 16, wherein the heat conducting plate is disposed in the hole under pressure, or by hot plugging, cold plugging or direct stamping.

19. The method of claim 18, wherein the hot plugging is to heat up the heat dissipating plate so that the hole is slightly larger than the heat conducting plate, dispose the heat conducting plate in the hole of the heat dissipating plate, and cool down the heat dissipating plate to achieve a tight contact between the heat conducting plate and the heat dissipating plate.

20. The method of claim 18, wherein the cold plugging is to cooling down the heat conducting plate so that the heat conducting plate is slightly smaller than the hole, dispose the heat conducting plate in the hole of the heat dissipating plate, and warm up the heat conducting plate to achieve a tight contact between the heat conducting plate and the heat dissipating plate.

21. The method of claim 16, wherein the heat dissipating plate and the heat conducting plate are made of copper, aluminum, alloys thereof, or a thermally conducting material.
